(19) United States
(12) Patent Application Publication
(10) Pub. No.: US 2014/0021955 A1
(43) Pub. Date: Jan. 23, 2014

(54) Gradient Coil with Precisely Positioned Coil Windings

(71) Applicants: Sascha Fath, Erlangen (DE); Jörg Riegler, Furth (DE); Johann Schuster, Oberasbach (DE); Lothar Schön, Neunkirchen (DE); Stefan Stocker, Grossenseebach (DE)

(72) Inventors: Sascha Fath, Erlangen (DE); Jörg Riegler, Furth (DE); Johann Schuster, Oberasbach (DE); Lothar Schön, Neunkirchen (DE); Stefan Stocker, Grossenseebach (DE)

(21) Appl. No.: 13/945,882

(22) Filed: Jul. 18, 2013

(30) Foreign Application Priority Data
Jul. 19, 2012 (DE) 102012212691.0

(51) Int. Cl. G01R 33/34

(52) U.S. Cl. CPC G01R 33/34007
USPC 324/322; 29/602.1

(57) ABSTRACT

A method for producing at least one saddle coil for a gradient coil layer for a magnetic resonance tomography system is provided. At least one half cylinder-shaped, premolded saddle coil is arranged between an inner shell and an outer shell of a casting apparatus. The shells of the casting apparatus are closed, and the space between the shells is filled with a casting compound.

This application claims the benefit of DE 10 2012 212 691.0, filed on Jul. 19, 2012, which is hereby incorporated by reference.

### BACKGROUND

The present embodiments relate to a method for producing a gradient coil layer.

Magnetic resonance devices (MRTs) for examining objects or patients using magnetic resonance tomography are known, for example, from DE10314215B4.

### SUMMARY

The scope of the present invention is defined solely by the appended claims and is not affected to any degree by the statements within this summary.

The present embodiments may obviate one or more of the drawbacks or limitations in the related art. For example, the production of a gradient coil layer is optimized.

### BRIEF DESCRIPTION OF THE DRAWINGS

FIG. 1 shows a cross-section through one embodiment of a pre-rolled saddle coil, a casting compound and an inner and outer shell of a casting apparatus during the production of a gradient coil arrangement;

FIG. 2 shows a cross-section of one embodiment of a cast saddle coil produced according to FIG. 1, with a very precise target radius;

FIG. 3 shows a perspective view of one embodiment of a saddle coil with an insulating plate and copper wire;

FIG. 4 shows a perspective view of one embodiment of a gradient coil arrangement with saddle coils; and

FIG. 5 shows a schematic representation of a magnetic resonance tomography (MRT) system.

### DETAILED DESCRIPTION OF THE DRAWINGS

FIG. 5 shows an imaging magnetic resonance device MRT 101 (e.g., disposed in a shielded room or Faraday cage F) having a whole body coil 102 with, for example, a tubular room 103 into which a patient couch 104 with a body 105 (e.g., an examination object such as a patient; with or without local coil arrangement 106) may be moved in the direction of the arrow z, so as to generate recordings of the patient 105 using an imaging method. A local coil arrangement 106 is arranged, for example, on the patient. Recordings of a subarea of the body 105 may be generated in a field of view (FOV) in a local area of the MRT with the local coil arrangement 106. Signals of the local coil arrangement 106 may be evaluated (e.g., converted into images, stored or displayed) by an evaluation device (e.g., including elements 168, 115, 117, 119, 120, 121) that may be connected via coaxial cable or radio (e.g., element 167) to the local coil arrangement 106, for example.

In order to examine a body 105 (e.g., an examination object or a patient) using a magnetic resonance imaging with a magnetic resonance device MRT 101, different magnetic fields attuned as accurately as possible to one another in terms of temporal and spatial characteristics are irradiated onto the body 105. A strong magnet (e.g., a cryomagnet 107) in a measuring cabin with, for example, the tunnel-shaped opening 103 generates a strong static main magnetic field B₀ that amounts to, for example, 0.2 Tesla to 3 Tesla or even more. The body 105 to be examined is moved, when mounted on a patient couch 104, into an approximately homogenous region of the main magnetic field B₀ in the field of view (FOV). An excitation of the nuclear spin of atomic nuclei of the body 105 takes place via magnetic high frequency excitation pulses B₁(x, y, z, t) that are irradiated via a high frequency antenna (and/or if necessary, a local coil arrangement) shown simplified as a body coil 108 (e.g., a multipart coil 108a, 108b, 108c). High frequency excitation pulses are generated, for example, by a pulse generation unit 109 that is controlled by a pulse sequence control unit 110. After amplification by a high frequency amplifier 111, the high frequency excitation pulses are routed to the high frequency antenna 108. The high frequency system shown in FIG. 5 is only indicated schematically. In some embodiments, more than one pulse generation unit 109, more than one high frequency amplifier 111 and a number of high frequency antennas 108 a, b, c are used in the magnetic resonance device 101.

The magnetic resonance device 101 includes a gradient coil arrangement 112 with, for example, three layers of gradient coils 112x, 112y, 112 z (e.g., gradient coil layers; if necessary, secondary coil layers and an active shim system; separated from one another by cooling planes passed through with water), with which magnetic gradient fields B_{G}(x, y, z, t) are irradiated during a measurement for selective slice excitation and local encoding of the measurement signal. The gradient coils 112x, 112y, 112z are controlled by a gradient coil control unit 114 and, if necessary, via amplifiers Vx, Vy, Vz. The gradient coil control unit 114, similarly to the pulse generation unit 109, is connected to the pulse sequence control unit 110.

Signals emitted by the excited nuclear spin of the atomic nuclei in the examination object are received by the body coil 108 and/or at least one local coil arrangement 106, amplified by assigned high frequency amplifiers 116 and further processed and digitalized by a receive unit 117. The recorded measured data is digitalized and stored as complex numerical values in a k-space matrix. An associated MR image may be reconstructed from the k-space matrix populated with values by a multi-dimensional Fourier transformation.

For a coil that may be operated both in transmit and also in receive mode, such as, for example, the body coil 108 or a local coil 106, the correct signal forwarding is regulated by an upstream transmit-receive switch 118.

An image processing unit 119 generates an image from measured data, which is shown to a user via a console terminal 120 and/or is stored in a storage unit 121. A central computing unit 122 controls the individual system components.

In MR tomography, images with a high signal-to-noise ratio (SNR) may be recorded with local coil arrangements (e.g., Coils, Local Coils). The local coil arrangements are antenna systems that are attached in the immediate vicinity on (e.g., anterior) or below (e.g., posterior), or on or in the body 105. With an MR measurement, the excited cores induce a voltage into the individual antennas of the local coil. The induced voltage is amplified with a low-noise preamplifier (e.g., LNA, Preamp) and routed to the receive electronics. In order to improve the signal-to-noise ratio, high field systems (e.g., 1.5 T-12 T or more) are also used in highly resolved images. If more individual antennas may be connected to an MR receive system than there are receivers present, a switching matrix (e.g., RCCS) is integrated, for example, between the receive antennas and receiver. This routes the currently active receive channels (e.g., the receive channels lying precisely in the field of view of the magnet) to the existing receiver. As a result, more coil elements than there are receivers present may be connected, since with a whole body coverage, only the coils that are disposed in the FoV and/or in the homogeneity volume of the magnet are to be read out.

An antenna system that may include, for example, one antenna element or an array coil including a plurality antenna elements (e.g., coil elements) may be referred to as a local coil arrangement 106, for example. The individual antenna elements are embodied, for example, as loop antennas (e.g., loops), butterfly, flexible coils or saddle coils. A local coil arrangement includes, for example, coil elements, a preamplifier, further electronics (e.g., coaxial cables), a housing, contacts and at least one cable with a plug, by which the local coil arrangement is connected to the MRT system. A receiver 168 attached on the system side filters and digitalizes a signal received by a local coil 106 (e.g., by radio wave) and transfers the data to a digital signal processing device that in most instances derives an image or a spectrum from the data obtained by a measurement and provides the image or the spectrum to the user (e.g., for subsequent diagnosis and/or storage).

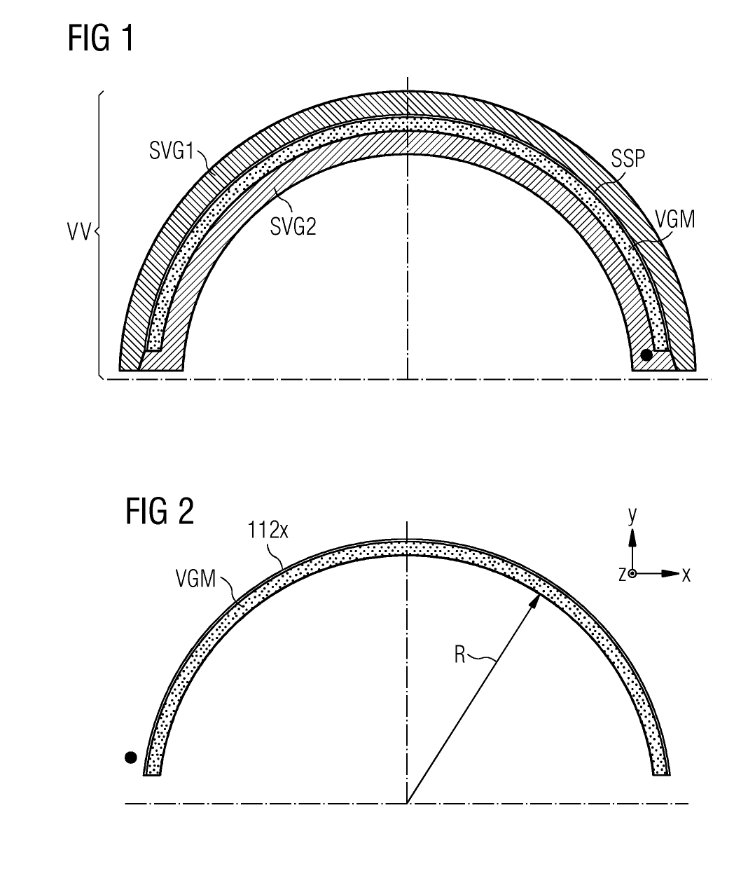

According to embodiments, FIGS. 1-4 show the production and structure of a saddle coil.

A gradient coil system (112x+112y+112z) of an MRI scanner 101 may include three primary coil layers 112x, 112y, 112z that are able to generate electromagnetic fields in the three spatial directions x, y, z. The coil layers 112x, 112y, 112z are arranged concentrically, for example, on a cylindrical surface of a cylinder. Three further secondary coil layers, which have the object of generating a counter field and thus compensating as far as possible for the field components directed outwards, are disposed at a radial distance, for example. Cooling planes through which water flows are disposed between the coil layers in order to discharge dissipation loss deposited in the coil system. An active shim system, which is used to improve the homogeneity of the basic magnetic field, may be disposed between the primary and secondary coils. The completely finalized gradient coil structure may be impregnated with a casting resin under vacuum and is hardened. During the production of a gradient coil, attention is to be paid to the positioning of the gradient conductors (e.g., coils). Small global and also local position deviations in the z-direction, in the tangential direction or in the radial direction may already lead to effective field errors (e.g., distortion, interferences on account of eddy currents, increased vibrations on account of poorer force compensation already result).

Conductive structures (e.g., SSP, KU) wound from flat/stranded conductors, which are glued to a carrier plate ISP, also simultaneously represent the insulation from the adjacent conductive structure (e.g., relative to the next gradient coil layer 112x, 112y, 112z radially inwards or outwards). For manufacturing reasons, a planar plate that is attached in the form of a half cylinder (e.g., according to FIG. 2) is developed in this way. This takes place, for example, with the aid of a rolling apparatus that is also used similarly to shape sheets. With this shaping process, deviations in shape away from the desired geometry may occur. The resulting radius R empirically approaches the target radius by variations in the setting parameters of the MRT. A subsequent correction is difficult to realize with a dense copper winding.

The following effects may occur: Deviations from the half cylinder shape; deviations from the target radius; and resilience of conductor loops result, on account of the elasticity of the compound with the support plate, in local form deviations.

All dimensional deviations result in the electromagnetic field generated by this coil including deviations from the pre-calculated spatial distribution. All described dimensional and form deviations result in the subsequent layers coming to rest on a larger radius than that pre-calculated. In order to render this compatible, a correspondingly large distance in terms of design is provided between the layers.

In one embodiment, half cylinder-shaped transversal coil layers may be produced with a comparatively more exact shape and radius R as follows: 1. Placing a coil SSP preformed in accordance with the prior art, for example, into a tool (in the form of a casting apparatus VV).

2. Closing the tool VV with the second mold half SVG1 under pressure. In this way, the coil layer very precisely assumes the desired shape (e.g., very precisely the radius R that the coil layer should have when integrated in the MRT 101).

3. Casting compound of the conductive clearances with a reaction resin molding material VGM, if necessary, under vacuum and/or with an increased temperature

4. Hardening of the reaction resin molding material with a closed tool VV, if necessary, under a temperature increase.

5. Opening the tool VV.

6. Demolding the pre-cast coil layer 112x.

The following advantages result using a method of one or more of the present embodiments: Receipt of the coil form after demolding when selecting a suitable reaction resin molding material; minimal dimensional and form deviation of the half cylinder-shaped saddle coils; minimized structure tolerances in the assembly of a number of coil layers one above the other (e.g., the outermost coil layer is disposed precisely on the pre-calculated radius); minimization of the distances to be provided between the individual coil layers (e.g., the sensitivity above all of the layers disposed on the larger radius is improved—); a minimization of the minimal distances to be provided between the individual coil layers may take place on account of the manufacturing tolerances so that the secondary coils may move further inwards, and a higher sensitivity of the secondary layers may thus be achieved; on account of the minimal radial manufacturing tolerances, minimized distortion errors that may be reproduced with primary and secondary coils disposed very close to one another, and a good shielding of the gradient coil in the manufacturing process that may be reproduced may also be achieved.

FIG. 1 shows a cross-section of one embodiment of a pre-rolled saddle coil SSP (e.g., before the state shown when rolled about a pin in the semi-circular arrangement shown; the saddle coil including, on at least one side, an insulation plate ISP and a coil of a gradient coil layer 112x arranged on the insulation plate ISP as a copper wire) between an inner shell SVG1 and an outer shell SVG2 of a casting apparatus VV, where a casting compound VGM (e.g., a reaction resin) was poured into the space formed between the inner shell SVG1 and the outer shell SVG2 (e.g., partially empty up to the saddle coil SSP).

FIG. 2 shows a cross-section of one embodiment of a saddle coil SSP taken from the casting apparatus VV (e.g., the shells SVG1, SBG2) that is produced, cast and hardened in accordance with FIG. 1, and has a very precisely achieved target radius R. The saddle coil SSP may have the target radius R as a gradient coil layer (e.g. 112x) or as part of a gradient coil layer (e.g. 112 x) including a number of saddle coils SSP integrated in the MRT 101.

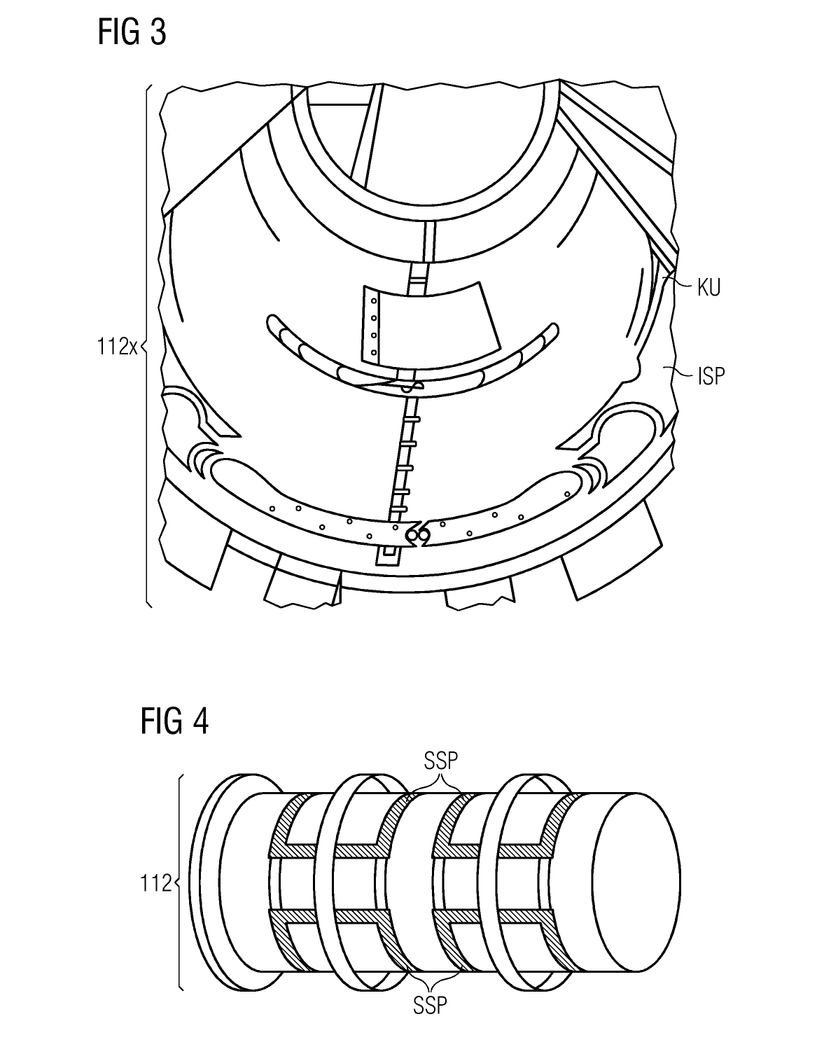

FIG. 3 shows a perspective view of one embodiment of a saddle coil SSP such as that, for example, in FIG. 2 with an insulating plate ISP (e.g., electrically insulating) and copper wire KU (e.g., Cu wire).

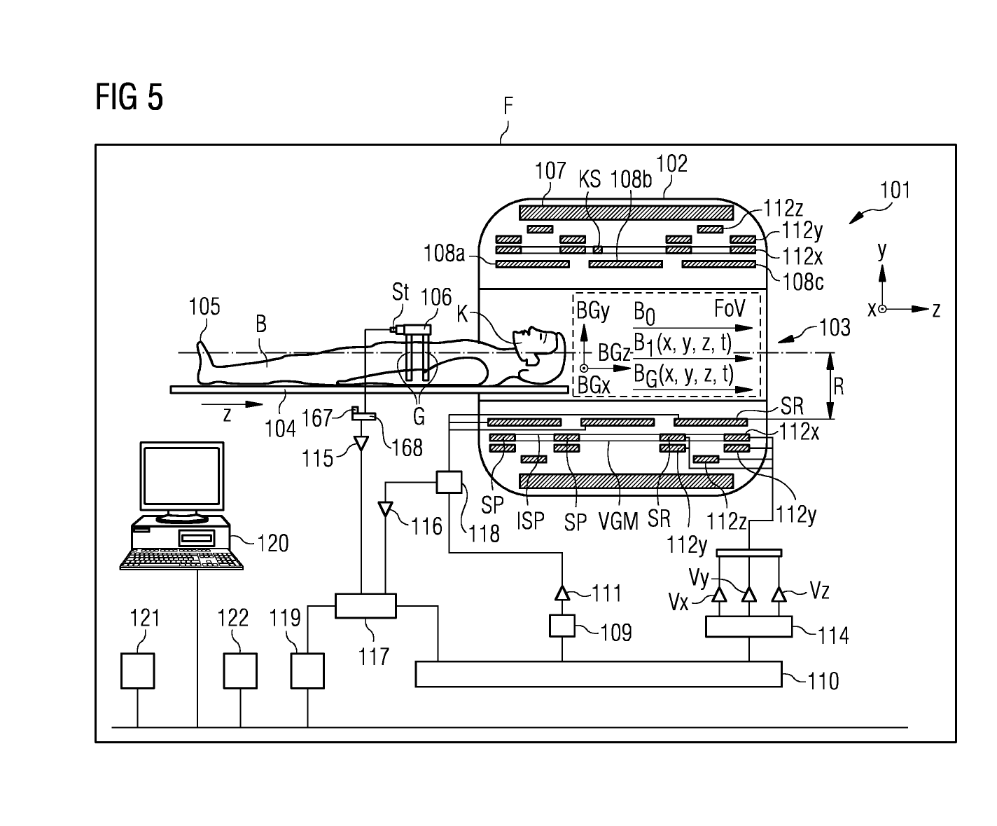

FIG. 4 shows a simplified perspective view of one embodiment of three gradient coil layers for three directions in a gradient coil arrangement 112 with, for example, two semi-circular saddle coils SSP on the left and two semi-circular saddle coils SSP on the right. The semi-circular saddle coils SSP (e.g., four semi-circular saddle coils SSP) form the gradient coil layer 112y for the gradient field in the y-direction.

It is to be understood that the elements and features recited in the appended claims may be combined in different ways to produce new claims that likewise fall within the scope of the present invention. Thus, whereas the dependent claims appended below depend from only a single independent or dependent claim, it is to be understood that these dependent claims can, alternatively, be made to depend in the alternative from any preceding or following claim, whether independent or dependent, and that such new combinations are to be understood as forming a part of the present specification.

While the present invention has been described above by reference to various embodiments, it should be understood that many changes and modifications can be made to the described embodiments. It is therefore intended that the foregoing description be regarded as illustrative rather than limiting, and that it be understood that all equivalents and/or combinations of embodiments are intended to be included in this description.

1. A method for producing at least one saddle coil for a gradient coil layer for a magnetic resonance tomography (MRT) system, the method comprising:
arranging the at least one saddle coil for the gradient coil layer for the MRT system between an inner shell and an outer shell of a casting apparatus, the at least one saddle coil being half cylinder-shaped and premolded;
closing the inner shell and the outer shell of the casting apparatus; and
filling space between the inner shell and the outer shell with a casting compound.

2. The method as claimed in claim 1, wherein the closing comprises closing the inner shell and the outer shell of the casting apparatus under pressure.

3. The method as claimed in claim 1, wherein the at least one saddle coil or the gradient coil assumes a shape of an arc between the inner shell and the outer shell.

4. The method as claimed in claim 1, wherein filling comprises filling with a resin as the casting compound.

5. The method as claimed in claim 4, wherein filling comprises filling with a reaction resin molding material as the resin.

6. The method as claimed in claim 1, further comprising casting under vacuum.

7. The method as claimed in claim 1, further comprising hardening the casting compound with a closed casting apparatus, with an increase in temperature during hardening compared with filling, or a combination thereof.

8. The method as claimed in claim 1, further comprising hardening the casting compound with the closed casting apparatus, wherein the closed casting apparatus is opened after hardening the casting compound.

9. The method as claimed in claim 8, further comprising demolding, using a molding tool, the at least one pre-cast saddle coil or the gradient coil layer after opening the casting apparatus.

10. The method as claimed in claim 8, wherein a radius of the at least one saddle coil or the gradient coil layer corresponds to a target radius of the at least one saddle coil, the gradient coil layer, or the at least one saddle coil and the gradient coil layer after the opening of the closed casting apparatus.

11. The method as claimed in claim 1, wherein two or more half shell-shaped saddle coils surround a periphery, a support, or the periphery and the support of a magnetic resonance tomography (MRT) bore and form a gradient coil position.

12. The method as claimed in claim 1, wherein only one saddle coil of a gradient coil arrangement is produced between the inner shell and the outer shell of the casting apparatus.

13. The method as claimed in claim 2, wherein the at least one saddle coil or the gradient coil assumes a shape of an arc between the inner shell and the outer shell.

14. The method as claimed in claim 2, wherein filling comprises filling with a resin as the casting compound.

15. The method as claimed in claim 3, wherein filling comprises filling with a resin as the casting compound.

16. The method as claimed in claim 2, further comprising casting under vacuum.

17. The method as claimed in claim 5, further comprising casting under vacuum.

18. The method as claimed in claim 6, further comprising hardening the casting compound with a closed casting apparatus, with an increase in temperature during hardening compared with filling, or a combination thereof.

19. The method as claimed in claim 17, further comprising hardening the casting compound with the closed casting apparatus,
wherein the closed casting apparatus is opened after hardening the casting compound.

20. A saddle coil for a gradient coil position for a magnetic resonance tomography system, prepared by a process comprising:
arranging the at least one saddle coil between an inner shell and an outer shell of a casting apparatus, the at least one saddle coil being half cylinder-shaped and premolded;
closing the inner shell and the outer shell of the casting apparatus; and
filling space between the inner shell and the outer shell with a casting compound.
